(19) United States
(12) Patent Application Publication
(10) Pub. No.: US 2015/0202662 A1
(43) Pub. Date: Jul. 23, 2015

(54) PROCESS FOR CLEANING CARBON NANOTUBES AND OTHER NANOSTRUCTURED FILMS

(71) Applicant: ANEEVE LLC dba ANEEVE NANOTECHNOLOGIES, LLC, (US)

(72) Inventor: HUAPING LI, Los Angeles, CA (US)

(73) Assignee: ANEEVE LLC dba ANEEVE NANOTECHNOLOGIES, LLC, Torrance, CA (US)

(21) Appl. No.: 13/648,600

(22) Filed: Oct. 10, 2012

Related U.S. Application Data
(60) Provisional application No. 61/545,986, filed on Oct. 11, 2011.

(51) Int. Cl. B08B 3/08; H01L 51/00; B82Y 30/00

(52) U.S. Cl. CPC B08B 3/08; H01L 51/0005; H01L 51/0025; H01L 51/0048

(57) ABSTRACT

A process for the cleaning of carbon nanostructure and similar materials and structures for removal of surfactant chemicals. The process includes washing the carbon nanostructures with concentrated acetic acid which may be glacial acetic acid. The cleaning process is also considered in carbon nanostructure film preparation with deposition of carbon nanostructures in solution with surfactant chemicals before the washing. Possible surfactants include sodium cholate (SC) and sodium dodecyl sulfate (SDS). Carbon nanostructure deposition on a substrate may be by various printing methods.

### PRIORITY

This application claims priority to U.S. Provisional Application No. 61/545,986, filed Oct. 11, 2011, the disclosure of which is incorporated herein by reference.

### BACKGROUND OF THE INVENTION

The field of the present invention is the cleaning of carbon nanostructure films used within devices such as transistors and transparent conductive films.

Pristine single-walled carbon nanotubes (SWCNTs) cannot be dispersed in solvent because of their macro size and strong hydrophobic interactions among them. To manipulate the SWCNTs requires chemical functionalization or surfactant dispersion that will affect the electric and surface properties of SWCNTs. Furthermore, these separated semi-conducting and metallic SWCNTs are extensively covered with sodium cholate and/or sodium dodecyl sulfate (SDS).

The common method is to use de-ionic water to clean up these dispersing agents from SWCNT surfaces on substrates either immobilized with amino groups or not. Other methods can be used to clean dispersing agents from SWCNTs, including oxidization reaction and thermal burning. However, these cleaning methods produce inconsistent results and don't remove all the dispersing agents from the SWCNT surfaces. Consequently, the end result of using the above cleaning methods often shows up as uncontrollable SWCNTs density and rough carbon nanotube surface that are indicative of chemical wrapping. These adverse effects directly influence practical applications of SWCNTs in electronics and sensors.

Density gradient ultracentrifuge (DGU) separated semi-conducting and metallic SWCNTs are wrapped with sodium cholate helices and dispersed with SDS, which exhibiting excellent water solubility. These separated semi-conducting and metallic SWCNTs aqueous solutions are facilely ink-inject printed on silicon wafer and plastic substrates to form nice white films. Directly washing these films using de-ionic water, no single SWNTs can be imaged with scanning electron microscope (SEM). With aminopropyltris (ethoxy) silane (APTES) modified silicon-wafer and plastic surfaces, SWCNT films are obtained by inserting these substrates in SWCNT solutions for a long period (over 10 hours). Their atom force microscopy images show rough SWCNT surfaces, indicating the incomplete removal of chemicals.

### SUMMARY OF THE INVENTION

The present invention is directed to a cleaning process for removal of surfactant chemicals from carbon nanostructures. The process includes washing with a carboxylic acid selected from the group consisting of acetic acid, propanoic acid and butanoic acid. Glacial acetic acid has been found of specific utility.

The cleaning process may also be considered in carbon nanostructure film preparation with deposition of carbon nanostructures in solution with surfactant chemicals before washing. Possible surfactants include sodium cholate (SC) and sodium dodecyl sulfate (SDS). Carbon nanostructure material deposition on a substrate may be by ink-jet printing, gravure roll-to-roll printing, screen and mask printing or various other printing methods.

Accordingly, it is an object of the present invention to provide an improved wash process for carbon nanostructures. Other and further objects and advantages will appear hereafter.

### BRIEF DESCRIPTION OF THE DRAWINGS

FIG. 1: AFM image (scale: 2 μm×2 μm) illustrates printed SWCNTs without acetic acid washing, showing surfactants helically wrapped around SWCNT surfaces.

FIG. 2: AFM image (scale: 2 μm×2 μm) illustrates printed SWCNTs on a silicon wafer after being washed with glacial acetic acid showing clean SWCNT surfaces.

### DETAILED DESCRIPTION OF THE PREFERRED EMBODIMENTS

CNT and other similar carbon materials and structures are here collectively referred to as carbon nanostructures. Embodiments of a cleaning process for films of such carbon nanostructures such as various CNT and other similar materials and structures such as nanoparticles, nanowires and monolayer materials from solutions with surfactants are here disclosed that:

Are able to effectively-remove chemicals which disperse SWCNTs such as surfactants from the material surface;

Leave the CNTs much cleaner with negligible movement in the film;

Have higher device yield;

Are easily integrated in a printable or semiconductor manufacturing process; and

Have increased CNT/device reproducibility.

This cleaning process removes surfactant chemicals from carbon naonostructures. The process includes washing the carbon nanostructures with a carboxylic acid selected from the group consisting of acetic acid, propanoic acid and butanoic acid. This process is applicable to any kind of carbon nanostructure. The embodiments described employ glacial acetic acid but the group is contemplated for use.

The removal of surfactants from carbon nanostructure surfaces by glacial acetic acid is believed to be a kinetic process where glacial acetic acid neutralizes surfactants (i.e. sodium cholate and SDS) to form corresponding acids that are immediately immiscible with acetic acid leading then to a breakdown of the neutralizes surfactants (i.e. sodium cholate helices and SDS micelles). The carbon components then form networks under the influence of gravitational forces and van de Waals interactions.

This kinetic process may also be distinguished from a simple carbon nanostructure film wash using de-ionic water where surfactants slowly diffuse into the aqueous solution determined by their thermodynamic equilibrium. In such a slow thermodynamic process, there is a high probability that carbon components also diffuse with the surfactants into the aqueous solution resulting in reduced carbon component density.

Compared with known techniques, the acetic acid wash has the advantageous results of increasing carbon nanostructure based transistor performance and increasing carbon nanostructure film optical transmissivity.

One embodiment of the process for fabricating a carbon nanostructure film ready for incorporation into electronic, optical and mechanical devices includes:

Creating a carbon nanostructure film on a substrate by printing semiconducting carbon nanostructures in solution using inkjet printing;

Washing the films with acetic acid (>30 minutes);

Making thin film transistors by printing silver nanoparticles on top of the printed SWNT films;

Printing polyethylamine (PEI)/lithium perchlorate (LiCIO⁴) ionic gel solution as top-gated materials on the silver nanoparticles.

Creation of a carbon nanostructure film typically employs chemical functionalization or surfactant dispersion of carbon nanostructure components. Surfactants are used such as sodium dodecylsulfonate (SDS) and sodium cholate (SC). In this embodiment, the surfactant dispersion is handled as ink and the film is deposited using printing techniques. Application is to a substrate such as a silicon wafer.

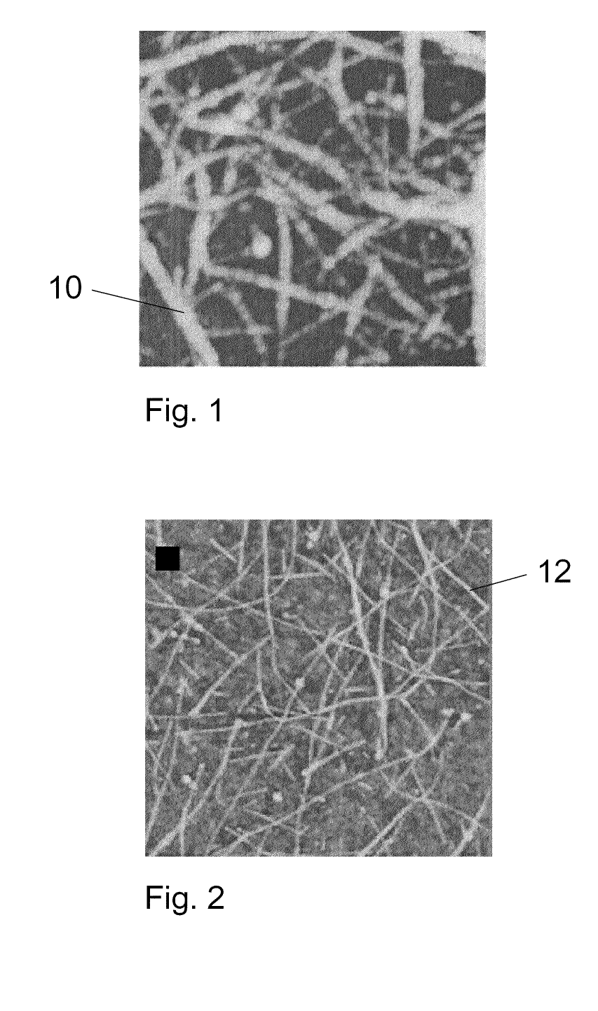

As an example, a semiconducting SWCNT solution inkjet printed on a silicon wafer was conventionally washed. The apparent diameters 10 of the CNT in FIG. 1 are seen to be large and non-uniform, reflecting the presence of surfactant on the CNT. The printed semiconducting SWCNT film illustrated in FIG. 2 was washed in glacial acetic acid. This image is bright and clear with smaller diameters 12 in comparison to those in FIG. 1, indicating an absence of surfactant on the CNT. FIG. 2 also shows smooth SWCNT surfaces, sharply contrasting with the periodic bamboo structures observed in FIG. 1. These images reflect that glacial acetic acid removes surfactants around the surface of SWCNTs compared to a conventional wash treatment.

Thin film transistors (TFT) have also been fabricated using SWCNTs and cleaned with acetic acid. Silver nanoparticles were printed to form transistor electrodes and the cleaned SWNCTs made up the transistor's semiconducting channel. The TFT backgated electric characteristics show mobility of 1.16 and an on/off ratio of 1000. Top gating these devices with polyethylamine (PEI)/lithium perchlorate (LiCIO⁴) ionic gel further enhanced the TFT device performance attributes.

Thus, the cleaning of carbon nanostructure based films and their incorporation into devices such as thin film transistors has been disclosed. While embodiments and applications of this invention have been shown and described, it would be apparent to those skilled in the art that many more modifications are possible without departing from the inventive concepts herein. The invention, therefore, is not to be restricted except in the spirit of the appended claims.

1-12. (canceled)

13. A process for removing at least one surfactant from a semiconducting single-walled carbon nanotube monolayer, comprising
washing the semiconducting single-walled carbon nanotube monolayer with a saturated carboxylic acid selected from the group consisting of acetic acid, propanoic acid and butanoic acid to remove the at least one surfactant.

14. The process of claim 13, wherein the saturated carboxylic acid is glacial acetic acid.

15. (canceled)

16. The process of claim 13, wherein the at least one surfactant is sodium cholate (SC).

17. The process of claim 13, wherein the at least one surfactant is sodium dodecyl sulfate (SDS).

18-22. (canceled)

23. The process of claim 13 further comprising
depositing an ink of the semiconducting single-walled carbon nanotube with the at least one surfactant on a substrate in a monolayer, by inkjet printing.

24. A process for removing at least one surfactant from a semiconducting single-walled carbon nanotube monolayer, comprising
depositing a solution of the semiconducting single-walled carbon nanotubes with the at least one surfactant in a monolayer on a substrate;
washing the monolayer of semiconducting single-walled carbon nanotubes with glacial acetic acid to remove the at least one surfactant.

25. (canceled)
